(19) United States
(12) Patent Application Publication
(10) Pub. No.: US 2004/0050690 A1
(43) Pub. Date: Mar. 18, 2004

(54) Magnetron sputtering apparatus

(76) Inventors: Gordon Robert Green, Bristol (GB); Robert Kenneth Trowell, Bristol (GB); Anthony William Barrass, Bristol (GB); Robert William Teagle, Somerset (GB); Ian Moncrieff, South Gloucestershire (GB); Stephen Robert Burgess, Gwent (GB)

Correspondence Address: Volentine Francos, 12200 Sunrise Valley Drive, Suite 150, Reston, VA, 20191, US

(21) Appl. No.: 10/433,231

(22) PCT Filed: Dec. 4, 2001
(86) PCT No.: PCT/GB01/05360

(30) Foreign Application Priority Data
Dec. 5, 2000 (GB) 0029568.3
Mar. 6, 2001 (GB) 0105466.7

(51) Int. Cl. C23C 14/32

(52) U.S. Cl. 204/192.13; 204/192.12; 204/298.03; 204/298.2

(57) ABSTRACT

A magnetic assembly (15) is mounted on a lead screw (12) on one side of a spunter target (14). A further lead screw (11) carries a counter weight (16). The lead screws can be rotated by a stepper motor (13) to adjust the lateral positions of assembly (15) and weight (16). The stepper motor and hence the assembly (15), can be rotated about a vertical axis by shaft (17) and motor (18) so that a magnetic field can be swept around the target (14). The position of the assembly (15) is varied in accordance with a process characteristic.

This invention relates to magnetron sputtering apparatus.

In all sputtering apparatus, a target is eroded by impinging particles, which are usually charged, and the displaced material is deposited on a workpiece or substrate.

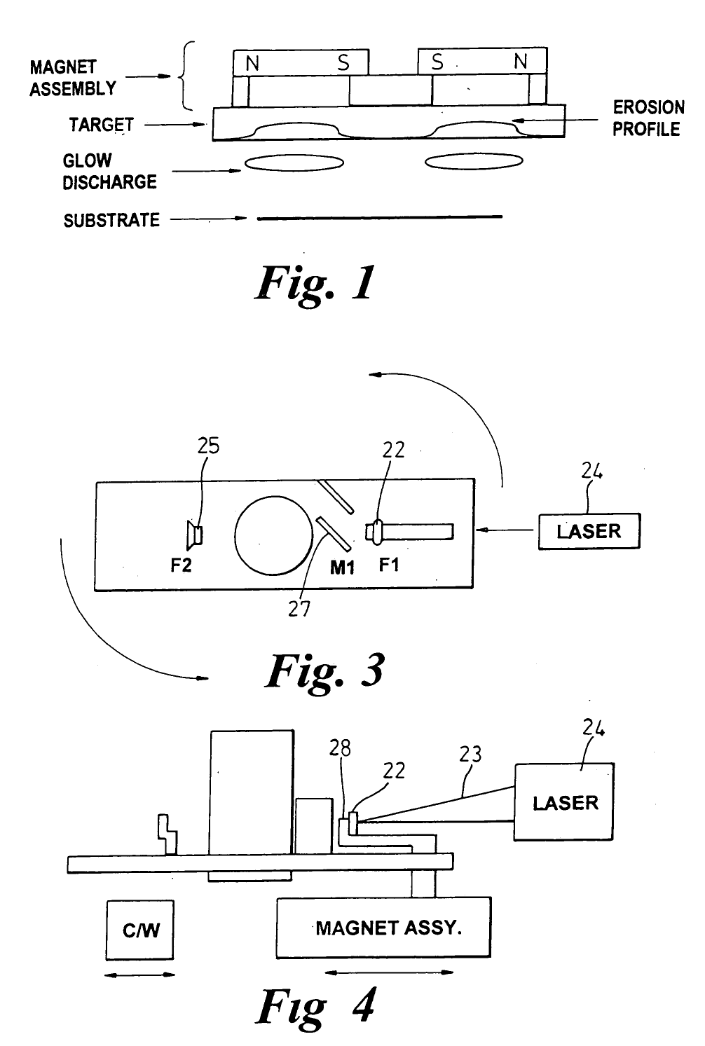

A particular class of sputter equipment commonly used in microelectronic and similar flat substrate applications is the planar magnetron. In a planar magnetron, the substrate is located close to and generally parallel to a planar target face. A glow discharge is created adjacent to the target face to provide a source of positive ions which impinge onto the target. A magnet assembly located behind the target face creates a magnetic field which serves to confine and intensify the glow discharge by means of electron entrapment. The magnetic field is designed to have a closed path such that electrons within the glow discharge are confined to move around it. This closed electron path is often referred to as a “race track”. By confining the electrons in this way, the density of the glow discharge is also confined to follow the race track shape. This in turn causes the erosion of the target face to be non-uniform, since the erosion rate depends on the local ion density in the glow discharge. Hence the erosion of the target also follows the race track shape. As a result the uniformity of deposited material is generally poor. FIG. 1 shows a typical planar magnetron.

In many applications the substrate can be moved relative to the target face and/or physical masks interposed between the target and substrate. By these means acceptable uniformity can be achieved with a planar magnetron. For single substrate processing chambers commonly used in microelectronic and similar applications, this approach is not applicable. In order to improve the uniformity to acceptable levels, the magnet assembly is moved, or “swept” behind the target. This arrangement is often known as a “swept field planar magnetron”. In most practical arrangements the magnets are swept in a rotary fashion and the target is circular. With this arrangement, the erosion profile on the target is the integration of the static race track erosion profile around the circle. The race track geometry can be optimised to give very good deposition uniformity with this simple arrangement. Other more complex motions have been proposed. Examples of such arrangements are shown in U.S. Pat. Nos. 4,746,417, 4,714,536, 6,013,159 and 6,132,565.

Target and race track geometry can in principle be optimised to give arbitrary uniformity. However two main factors cause practical systems to progressively deviate from an optimised arrangement as the target erodes. Firstly, as the eroding surface moves back into the target, the local field strength changes as the magnet assembly is approached. This causes a change in the shape of the glow discharge, which in turn results in a change to the erosion profile. Secondly, the deposition flux emitted from the target possesses a defined angular distribution with respect to the target face. Thus as the target erodes and the target face becomes non-planar, that flux is thrown off in a slightly different direction. For many applications the target and race track geometry can be optimised to give acceptable uniformity throughout target life. However for critical applications such as SAW and BAW filters, it is necessary to adjust the geometry many times throughout the life of a target in order to maintain uniformity within acceptable limits.

The present invention consists in sputtering apparatus including a target, a power source for the target and a magnetron disposed adjacent the target, including at least one magnet assembly movable laterally and rotationally relative to the target characterised in that the apparatus further includes control apparatus for varying the lateral position of an operational magnet of the assembly over the life of the target in accordance with a process characteristic.

The applicants have determined that a particular convenient process characteristic for the control of lateral position is the accumulated power supplied to the target, because this is an indirect measurement of the degree of target erosion. In particular the applicants have determined that an algorithm based on a fourth order polynomial function derived from accumulated power data can be used to predict the optimum position of the magnet assembly. In this case it may be most convenient to have a pre-set position sequence based on a look-up table or the like, but it would be equally possible to monitor the profile or part of the profile of the target and the control the magnet position accordingly. Similarly the magnet position could be controlled on a run by run basis by, for example, monitoring the uniformity of the material actually deposited on the work piece and in particular the material deposited at the base of a recess in the workpiece.

Although the system could be operated utilising a stepper motor or other controllable positional adjustment mechanism to achieve a particular magnet assembly, it is preferred that the apparatus also includes a magnet position detector for providing a true position signal to the control apparatus. In one particularly preferred arrangement the position detector includes a reflector on the magnet assembly and a laser system for shining light on the reflector and for detecting the hence reflected light. At least one other reflector may be provided on the apparatus to provide a further, fixed lateral position signal, which will enable the laser detector to also measure the rotational speed of the magnet assembly.

Conveniently the magnet assembly may be mounted on a worm gear or lead screw extending generally parallel to the target and the apparatus may further include a stepper motor for rotating the gear or screw to move the magnet laterally. In this case the sputter apparatus may further include a motor for rotating the worm gear or lead screw about an axis orthogonal to its own axis. Vertical movement of the magnet can be achieved by using a similar approach.

Alternatively the magnet assembly can comprise an array, either lateral or lateral and vertical, of electromagnets and the movement can be achieved by powering a selected magnet or arrays of magnets.

In either case the vertical position may be dependent on target voltage.

From a further aspect the invention consists in a method of controlling a magnetron assembly having a magnetic assembly laterally or laterally and vertically moveable with respect to a target characterised in that the method includes monitoring a process characteristic and adjusting the position of an operational magnet of the assembly in accordance with that characteristic.

Preferably the characteristic, which can be any appropriate characteristic including those specified above, is monitored remotely.

In any of the apparatus or methods the magnetron may be unbalanced or capable of being operated in an unbalanced mode.

Although the invention has been defined above it is to be understood that it includes any inventive combination of the features set out above or in the following description.

The invention may be performed in various ways the specific embodiments will now be described, by way of example, with reference to the accompanying drawings, in which:

FIG. 1 shows the general layout of a magnetron;

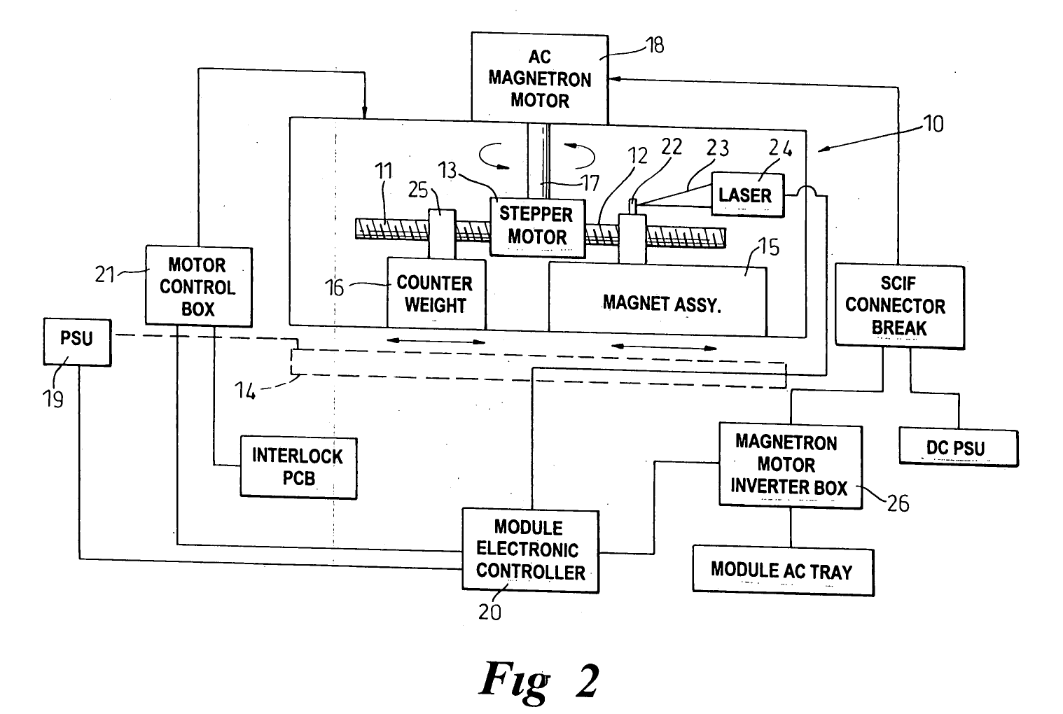

FIG. 2 is a schematic side view of a magnetron assembly and its associated control;

FIG. 3 is a view from above showing specific features of detection system;

FIG. 4 is a corresponding side view of the arrangement shown in FIG. 3;

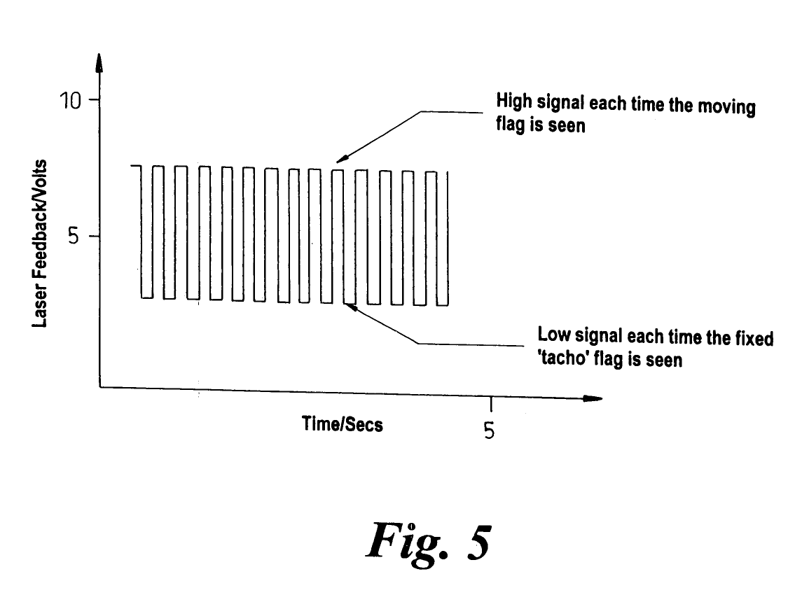

FIG. 5 is a graphical display of the laser output; and

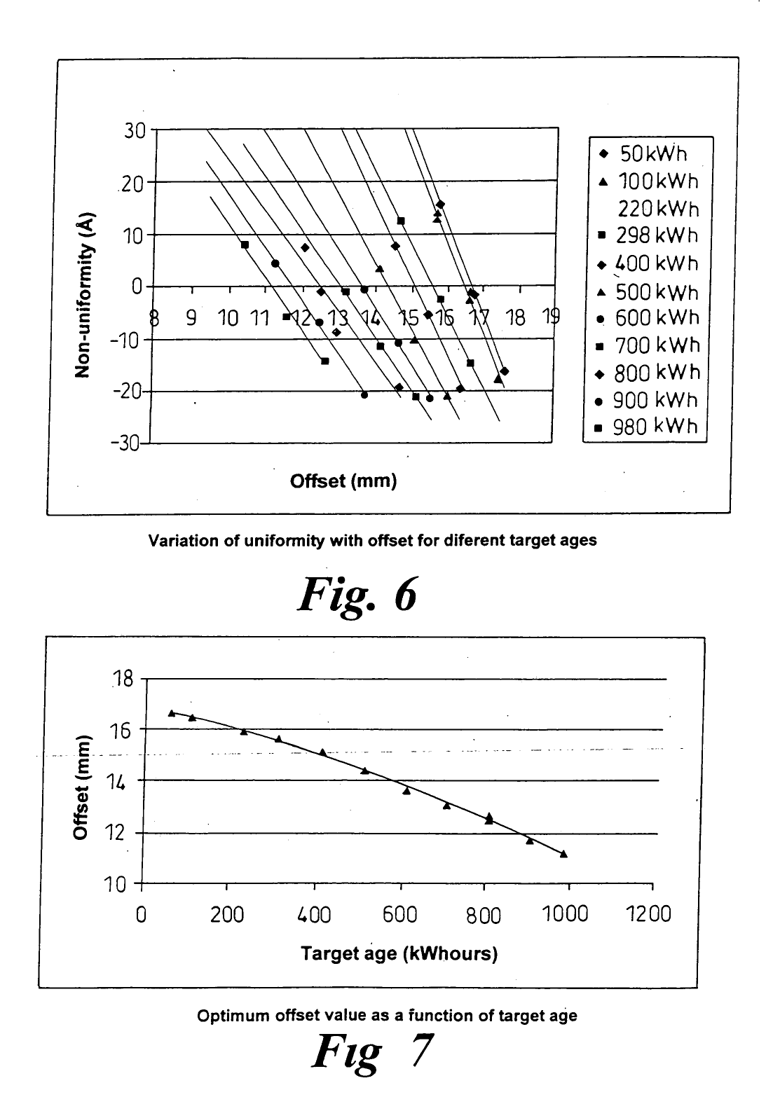

FIG. 6 is a graph of non uniformity across the target plot against the offset of the magnet; and

FIG. 7 illustrates optimised offset value against target age in KW hours; and

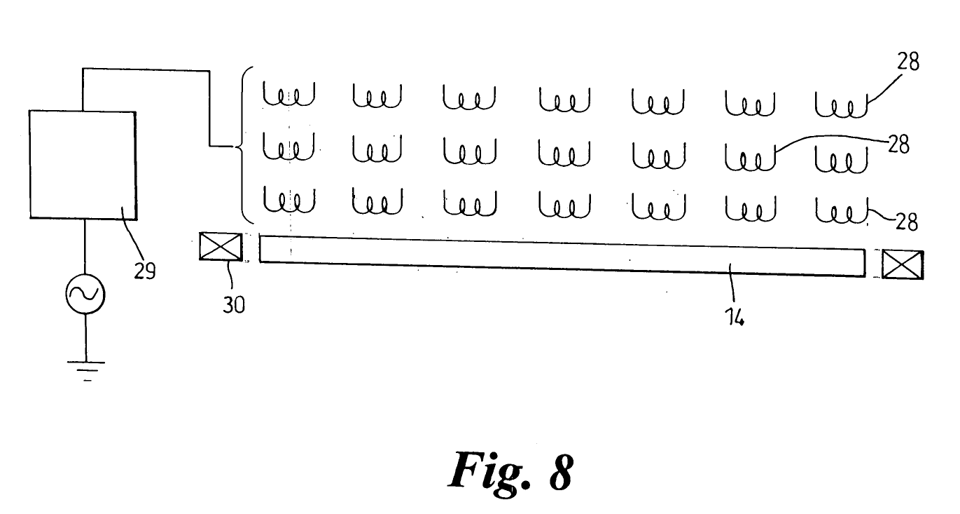

FIG. 8 is a schematic view of an alternative approach to the magnetic assembly.

In FIG. 1 oppositely threaded worm gears or lead screws 11, 12 are mounted on a stepper motor 13 to extend generally parallel to a target which is illustrated in broken line at 14. A magnetic assembly 15 is mounted on the lead screw 12, whilst the lead screw 11 carries a corresponding counterweight 16. The stepper motor 13 is supported on a vertical shaft 17, which can in turn be rotated by a motor 18. Rotation of the shaft 17 causes the magnetic assembly 15 to sweep a path above the target 14 and the positions of the magnetic assembly 15 and the counterweight 16 can be radially adjusted by means of the stepper motor 13, so as to change the path swept out. At this stage the arrangement is essentially that described in U.S. Pat. No. 6,132,565 and it will be appreciated that the counterweight could be another magnetic assembly. However, in the prior art, there is no indication or suggestion of how the magnetic assemblies should be controlled. The applicants have determined, surprisingly, that it is possible and desirable to control the magnetic assembly position in accordance with a process characteristic so as to optimise the uniformity of deposition, without the need to open the vacuum chamber to inspect the wear on the target. As is explained in more detail below the supposition that uniform target wear automatically gives uniform deposition is not correct for all target/substrate configurations.

In particular the applicants have discovered that the wear of a target, in any particular set up, is a predictable function of the power supplied to the target in this case by the power supply unit 19. Accordingly, in the applicants' apparatus, a control module 20, which is responsive to the power supply unit 19 controls, through a control box 21, the stepper motor 13 to adjust the position of the magnetic assembly 15 in accordance with the cumulative power supplied during the life of the target 14. It will be appreciated that careful monitoring of the operation of the stepper motor 13 could be used to determine the position of the magnetic assembly, but the applicant has determined that it is preferable to remotely and precisely detect that position using a laser based position detector system.

Thus the magnetic assembly 15 carries a small white ceramic reflector flag 22 off which a laser beam 23, which is emitted by laser 24, can be bounced and the returning beam is detected by a position sensitive device mounted in the laser 24. Alternatively a linear encoder could be used. This information is then fed to the controller 20 so that the magnetic assembly can be precisely located under full feedback control.

The laser 24 can also be used to monitor the rotational speed of the magnetic assembly, by means of a further ceramic reflector flag 25, which is located in a fixed position on the worm screw 11. It will be noted that it is 180° displaced from the flag 22. It is positioned just inside the measurement range of the laser 24 and is outside the travel limit of the moveable flag 22. As can be seen from FIG. 4, the flags produce respective high and low signals, creating a square wave output, and the time taken between the detection of a high signal and its succeeding low signal (or vice-versa) is an indication of rotational speed. This could be replaced by a rotatory encoder. The controller 20 can then control the speed of the motor 18, via the inverter box 26.

Accurate rotation speed control is important, because it also effects target wear and so the optimised position of the magnetic assembly 15 would vary for different rotational speeds.

The applicants' apparatus is typically operated at 300 rpm during sputtering and whilst the position of the magnetic assembly 15 is being adjusted.

A mirror 27 is provided to deflect the laser beam 23 away from the laser 24 so that the only reflections seen are those generated by the flags. A correctly located mirror 27 also prevents false reflections from the shaft 17. It will, in this connection, also be noted that the bracket 28 on which the flag 22, is mounted is coloured black to prevent false reflections.

As the only reflections are, therefore, flag-generated, the system can have a laser peak hold feature, which enables the laser to hold the peak from the last in-range measurement until the next “in-range” flag is seen. This avoids the need for excessively high sampling rates.

In normal operation the controller 20 will calculate the desired position of the magnetic assembly, each time the sputtering apparatus is moved from its “standby” status to its “ready” status and cause any necessary adjustment to take place.

Instead, a practical way to optimise the geometry of a swept field planar magnetron for a given process is to adjust the radial “offset” between a datum on the magnet assembly and the centre of rotation. FIG. 6 shows how the film non-uniformity across the substrate varies with offset distance for a range of different target ages. A different offset is required to give optimal non-uniformity at each. FIG. 7 shows how the optimum offset varies throughout target life

However, it is also possible, in certain processes, to use the arrangement for real time control of the uniformity in direct response to monitoring of the uniformity of deposition on a substrate, for example by using a substrate weighing process.

The magnet assembly 15 could also be similarly mounted for vertical movement, for example by configuring the shaft 17 as a rodless cylinder or rendering it telescopic. The vertical position may then be altered in accordance with target erosion for a fixed applied power to maintain a constant magnetic field extension in front of the target surface.

The lateral adjustments mentioned above aim to achieve greater uniformity of erosion over the face of the target, and thus across a workpiece but the target erosion also affects the level of deposition and thus the uniformity of deposition thickness wafer-to-wafer. Typically that is overcome by variations in the source to substrate distance, the process time or target power levels, but in certain processes, such as the self-ionised sputtering of barrier layers for semiconductor devices, it may not be possible to adjust these variables without changing the process characteristics. For such self-ionised sputtering processes the magnetic field from assembly 15 extending beyond the target surface facing the substrate is a key process characteristic. If the target erodes this inevitably changes. A ‘work around’ presently used, is to adopt thin targets that must be changed more frequently thus ensuring that in production only a small change in process occurs between the first and the last workpiece processed by each target. Here, however it is proposed that by moving the magnetic field back, as the target erodes, the magnetic field extension is stabilised. Further, it has been found that when operating the target in a self-ionising mode, as the target erodes the target voltage drops significantly for a fixed applied power. It is not presently known why this is the case, but it does provide a useful feedback of target erosion and may therefore be used to control the movement of assembly 15. An alternative would be the use of a look-up table that a stored program device would use as kw/hrs were accumulated on the target. As set points of accumulated power the assembly 15 would be moved back a predetermined amount known from experimentation to stabilise the process.

Particularly when both lateral and vertical adjustment is desired, it may be efficacious to reconfigure the magnetic assembly by replacing it by array of electromagnets, as schematically illustrated in FIG. 8. By having a series of layers of concentric rings of electromagnets 28 and a power supply that can individually power individual electromagnets 28, then the movement (lateral, vertical and rotational), can be achieved by the control mechanism 28 powering the appropriate electromagnet or magnets 28 at the relevant point in the process time. Thus, for example, in any individual layer the magnetic field may be swept around the electromagnets like a beam on a radar screen and the layer utilised can be varied in accordance with target erosion. Indeed more sophisticated control could utilise different magnets in different layers simultaneously to enhance uniformity of deposition. For example the magnetic field may be kept, advantageously at a lower level towards the edge of the target, as compared with the centre.

Without affecting the generality of this invention equivalents of the laser and reflective flag detailed here may also be utilized such as linear encoders, linear potentiometers, comb and optical switch and other equivalent devices capable of accurately indicating linear displacement by electrical or optical means. Further, the counterweight 16 need not be the same mass as the magnet assembly 15 and therefore needs to be moved over greater distances in the same time as the magnet assembly is moved e.g. through a different pitch to the threads of lead screws 11 and 12 or by the provision of differing gearing ratios and/or separate stepper motors that may independently turn shafts 11 and 12 at different rates.

It has also been determined by experimentation with the apparatus of the invention that the long held assumption that uniform erosion of the target would lead to uniform deposition on the wafer does not necessarily hold true for all magnetron assemblies and in particular for unbalanced magnetrons.

For a particular unbalanced magnetron consisting of the assembly as described here, with a further electromagnet 30 arranged about the periphery of target 14, table 1 shows that uniformity of deposition and coverage is optimised by choosing a magnet assembly offset of 13 mm however this does not provide full face erosion. Therefore a second offset of e.g. 24 mm may be used from time to time that this does provide full face erosion of the target but at a lower level of uniformity and coverage on the substrates. It is therefore possible to run cleaning cycles of full face erosion as is known to be necessary for reduced particulates (e.g. when a wafer is not present and/or when a shutter blocks the sputter path to the substrate holder). Or the magnet assembly may be moved frequently and/or continuously, providing a better compromise of uniformity of deposition and full face target erosion that is desirable to increase target life time and reduce particulate generation than is available from a fixed magnet offset.

Through target life, whilst full face erosion offset will not change, that for optimal uniformity and coverage will change as the target is eroded. This optimal offset may therefore be selected or continuously varied through target life in response to experimental data and recalled by reference to accumulated target power.

TABLE 1

| Magnet | Full Face | 1 sigma | Wafer Centre | Wafer Edge |
|---|---|---|---|---|
| Offset | erosion? | Uniformity | Coverage | Coverage |
| 13 mm | No | 4.2% | 42% | 37% |
| 24 mm | Yes | 6.7% | 32% | 32% |

“1 sigma uniformity”, is an industry standard term being percentile more than one standard deviation away from the mean of thickness measurements calculated by industry standard equipment. Lower number is better uniformity.

“Coverage” is base of hole coverage compared to coverage on the field of the wafer.

This leads to the possibility of selecting the preferred magnet offset or set of offsets for a particular target to wafer distance as may be selected for varying applications e.g. sputtering of metals and reactive sputtering in the same chamber.

It is further found that the coverage in the base of a hole is improved (as a percentage of material deposited above the hole) by selecting a magnetron offset other than that which gives full face erosion and has therefore previously been regarded as optimal.

The ability to move the magnetron under control of a stored program thereby allows the separate desirable traits of uniformity, base of hole coverage and particulate minimisation both across a wafer and from wafer to wafer through a target's life to be met by different and/or differing magnetron offsets.

1. Sputtering apparatus including a target, a power source for the target and a magnetron disposed adjacent the target, including at least one magnet assembly movable laterally and rotationally relative to the target characterised in that the apparatus further includes control apparatus for varying the lateral position of an operational magnet of the assembly over the life of the target in accordance with a process characteristic.

2. Sputtering apparatus as claimed in claim 1 wherein the process characteristic is the accumulated power supplied to the target.

3. Sputtering apparatus as claimed in claim 1 wherein the vertical position of the magnet is also variable in accordance with a second process characteristic.

4. Sputtering apparatus as claimed in claim 3 wherein the second process characteristic is the target voltage.

5. Sputtering apparatus as claimed in any one of the previous claims further comprising a magnet assembly position detector for providing a position signal to the control apparatus.

6. Sputtering apparatus as claimed in claim 5 wherein the position detector includes a reflector on the magnet assembly and a laser system for shining a light on the reflector and for detecting the hence reflected light.

7. Sputtering apparatus as claimed in claim 5 wherein the position detector is a linear encoder.

8. Sputtering apparatus as claimed in any one of the preceding claims wherein the magnet assembly is mounted on a worm gear or lead screw extending generally parallel to the target and the apparatus further includes a stepper motor for rotating the gear or screw to move the magnet laterally.

9. Sputtering apparatus further including a counter balance weight mounted on a lead screw.

10. Sputtering apparatus as claimed in claim 9 wherein the weight is moved more quickly than the magnetic assembly.

11. Sputtering apparatus as claimed in any one of claims 8 to 10 wherein the apparatus further includes a motor for rotating the worm gear or lead screw about an axis orthogonal to its axis.

12. Sputtering apparatus as claimed in any one of claims 1 to 4 wherein the magnet assembly is an array of electromagnets and the varying of the lateral position of the magnet is achieved by varying the power supplied to the assembly to activate one or more electromagnets within the array.

13. Sputtering apparatus as claimed in any one of the preceding claims wherein the magnetron is an unbalanced magnetron.

14. Sputtering apparatus as claimed in claim 13 wherein the magnetron is unbalanced by magnets or an electromagnet encircling the region of the target.

15. Sputtering apparatus as claimed in any one of the preceding claims wherein the process condition is the depth of material deposited at the base of a recess per unit time.

16. A method of controlling a magnetron assembly having a magnet assembly laterally or vertically and laterally movable with respect to a target characterised in that the method includes monitoring a process characteristic and adjusting the position of an operational magnet of the assembly in accordance with that characteristic.

17. A method as claimed in claim 16 wherein the characteristic is monitored remotely.

18. A method as claimed in claim 16 or claim 17 wherein the magnet assembly is an array of electromagnets and the movement is achieved by selection of the electromagnets in the array which are to be activated.

19. A method as claimed in any one of claims 16 to 18 wherein the process characteristic is the accumulated power supplied to the target and/or the depth of material deposited at the base of a recess per unit time.

20. A method as claimed in any one of claims 16 to 19 wherein the magnetron assembly operates in an unbalanced mode.

21. A method as claimed in claim 20 wherein a selection is made between balanced and unbalanced modes of the magnetron.
